(19) United States
(12) Patent Application Publication
(10) Pub. No.: US 2011/0030900 A1
(43) Pub. Date: Feb. 10, 2011

(54) PLASMA CHAMBER HAVING SWITCHABLE BIAS POWER AND A SWITCHABLE FREQUENCY RF MATCH NETWORK THEREFOR

(75) Inventors: Jinyuan CHEN, Shanghai (CN); Gerald Yin, Shanghai (CN)

Correspondence Address: NIXON PEABODY, LLP, 401 9TH STREET, NW, SUITE 900, WASHINGTON, DC, 20004-2128, US

(73) Assignee: ADVANCED MICRO-FABRICATION EQUIPMENT, INC. ASIA

(21) Appl. No.: 12/851,381

(22) Filed: Aug. 5, 2010

(30) Foreign Application Priority Data
Aug. 5, 2009 (CN) 200910055935.9

(51) Int. Cl. C23F 1/08; H03K 17/00

(52) U.S. Cl. 156/345.48; 307/112

(57) ABSTRACT

A plasma chamber having a switchable bias frequency superimposed onto plasma source frequency and applied to the cathode. A power supplier capable of generating multiple RF bias frequencies is coupled into a match network through a switch. The match network couples one of the bias frequencies to the cathode. Another match network applied a source RF power to the cathode. One parallel connection of variable shunt capacitor and fixed capacitor are provided between ground and input of the switch and another is connected between ground and the input of the source RF match network.

### BACKGROUND

1. Field of the Invention

The subject invention relates to RF power suppliers and matching networks used in plasma chambers and, more specifically, RF power suppliers and matching networks enabling application of multiple-frequency RF power.

2. Related Art

Plasma chambers utilizing dual or multiple RF frequencies are known in the art. Generally, a plasma chamber of dual frequencies receives RF bias power having frequency below about 15 MHz, and an RF source power at higher frequency, normally 27-200 MHz. In this context, RF bias refers to the RF power which is used to control the ion energy and ion energy distribution. On the other hand, RF source power refers to RF power which is used to control the plasma ion dissociation or plasma density. For some specific examples, it has been known to operate etch plasma chambers at, e.g., bias of 100 KHz, 2 MHz, 2.2 MHz or 13.56 MHz, and source at 13.56 MHz, 27 MHz, 60 MHz, 100 MHz, and higher.

Recently it has been proposed to operate a plasma chamber at one bias frequency and two source frequencies. For example, it has been proposed to operate a plasma etch chamber at bias frequency of 2 MHz and two source frequencies of 27 MHz and 60 MHz. In this manner, the dissociation of various ion species can be controlled using the two source RF frequencies. Regardless of the configurations, in the prior art each frequency is provided by an individual RF power supplier and each individual power supplier is coupled to an individual matching network.

FIG. 1 is a schematic illustration of a prior art multiple frequency plasma chamber arrangement, having one bias RF power and two source RF power generators. More specifically, in FIG. 1 the plasma chamber 100 is schematically shown as having an upper electrode 105, lower electrode 110, and plasma 120 generated in between the two electrodes. As is known, electrode 105 is generally embedded in the chamber's ceiling, while electrode 110 is generally embedded in the lower cathode assembly upon which the work piece, such as a semiconductor wafer, is placed. As also shown in FIG. 1, a bias RF power supplier 125 provides RF power to the chamber 100 via match circuit 140. The RF bias is at frequency f1, generally 2 MHz or 13 MHz (more precisely, 13.56 MHz), and is generally applied to the lower electrode 110. FIG. 1 also shows two RF source power suppliers 130 and 135, operating at frequencies f2 and f3, respectively. For example, f2 may be set at 27 MHz, while f3 at 60 MHz. The source power suppliers 130 and 135 deliver power to chamber 100 via match networks 145 and 150, respectively. The source power may be applied to the lower electrode 110 or the top electrode 105. Notably, in all of the Figures the output of the match networks is illustrated as combined into a single arrow leading to the chamber. This is used as a symbolic representation intended to encompass any coupling of the matching networks to the plasma, whether via the lower cathode, via an electrode in the ceiling, an inductive coupling coil, etc. For example, the bias power may be coupled via the lower cathode, while the source power via an electrode in the showerhead or an inductive coil. Conversely, the bias and source power may be coupled via the lower cathode.

### SUMMARY

The following summary of the invention is intended to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Various aspects of the subject invention provide plasma chamber having a switchable bias frequency superimposed onto plasma source frequency and applied to the cathode. According to an embodiment of the invention, a power supplier capable of generating multiple RF bias frequencies is coupled into a match network through a switch. The match network couples one of the bias frequencies to the cathode. Another match network applies a source RF power to the cathode. One parallel connection of variable shunt capacitor and fixed capacitor are provided between ground and input of the switch and another is connected between ground and the input of the source RF match network. The fixed capacitor provides protection for its parallel-connected variable shunt capacitor.

According to an aspect of the invention, an RF matching circuitry is provided having capability for switchably coupling one of two bias frequencies and one source frequency to a cathode. The circuitry comprises: a switch having one input and a first and a second outputs; a first match network having input coupled to the switch's first output and output coupled to the cathode, the first match network is tuned to operate at a first bias frequency below 10 MHz; a second match network having input coupled to the switch's second output and output coupled to the cathode, the second match network is tuned to operate at a second bias frequency higher than the first bias frequency but below 15 MHz; and, a third match network having output coupled to the cathode, the third match network is tuned to operate at a source frequency higher than the second bias frequency. The circuitry may also comprise: a parallel resonance circuit coupled between the output of the third match network and the cathode, the parallel resonance circuit can be tuned to be centered at the same frequency as the second bias frequency; a variable shunt capacitor coupled between ground and the input of the switch; a second variable shunt capacitor coupled between ground and the input of the third match network; a fixed capacitor coupled between ground and the input of the switch; and/or a second fixed capacitor coupled between ground and the input of the third match network.

According to an aspect of the invention, an RF matching circuitry is provided, having the capability for switchably coupling one of two bias frequencies to a cathode. The circuitry comprises: a switch having one input and a first and a second outputs; a first match network having input coupled to the switch's first output and output coupled to the cathode, the first match network tuned to operate at a first bias frequency below 10 MHz; a second match network having input coupled to the switch's second output and output coupled to the cathode, the second match network tuned to operate at a second bias frequency higher than the first bias frequency but below 15 MHz; a variable shunt capacitor coupled between ground and the input of the switch; and a fixed capacitor coupled between ground and the input of the switch.

According to another aspect of the invention, a plasma processing chamber operable with two switchable RF bias power is provided, comprising: a chamber body configured to maintain plasma within an evacuated interior; a cathode configured for coupling RF energy to the plasma; a first RF power generator operable to selectively generate either a first bias frequency below 10 MHz or a second bias frequency higher than the first bias frequency but below 15 MHz; a switch having an input coupled to the first RF power generator and having a first and second outputs; a first match network having input coupled to the switch's first output and output coupled to the cathode, the first match network tuned to operate at the first bias frequency; a second match network having input coupled to the switch's second output and output coupled to the cathode, the second match network tuned to operate at the second bias frequency; a second RF power generator operable to generate RF source power at frequency higher than 15 MHz; and, a third match network having input coupled to the second RF power generator and output coupled to the cathode. In one example the first bias frequency is about 2 MHZ, the second bias frequency is about 13 MHz, and the source power frequency is one of 27 MHz, 60 MHz, and 100 MHz. The circuitry may further comprise a parallel resonance circuit coupled between the output of the third match network and the cathode, the parallel resonance circuit tuned to be centered at about 13 MHz with a 2 MHz band. The circuitry may further comprise parallel connection of a variable shunt capacitor and a fixed capacitor coupled between ground and the input of the switch. The circuitry may further comprise parallel connection of a variable shunt capacitor and a fixed capacitor coupled between ground and the input of the third match network.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 is a schematic illustration of a prior art multiple frequency plasma chamber arrangement, having one bias RF power and two source RF power generators.

FIG. 2 is a schematic illustration of a first embodiment of the invention of a multiple frequency plasma chamber arrangement, having two bias RF power and one source RF power generators.

FIG. 3 depicts an embodiment of an RF power matching circuitry.

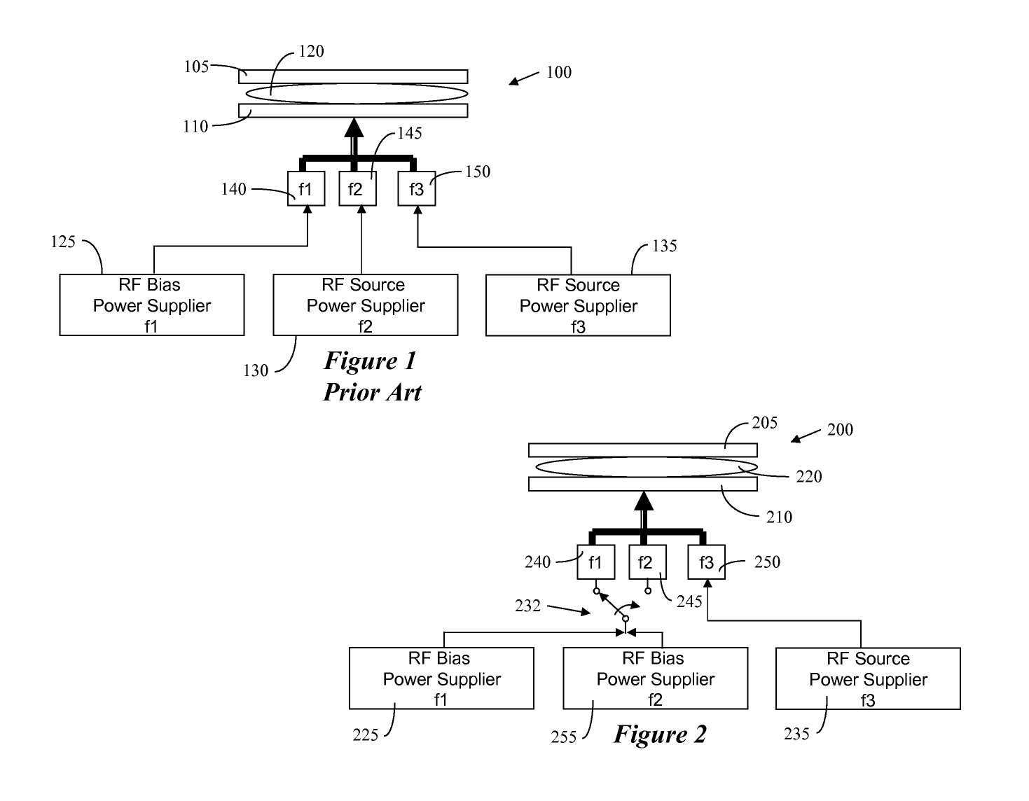

### DETAILED DESCRIPTION

FIG. 2 is a schematic illustration of an embodiment of the invention of a multiple frequency plasma chamber arrangement, having two switchable RF bias power coupled to a match network. In FIG. 2, two RF bias power suppliers 225 and 255 provide switchable f1 and f2 RF bias power to the chamber 200 via switch 232 that is coupled to match circuits 240 and 245, respectively. The RF bias is at frequency f1, generally 2 MHz or 2.2 MHz, while the RF bias frequency f2 is generally 13 MHz (more precisely, 13.56 MHz). Both RF bias are generally applied to the lower electrode 210. In this manner, an improved ion energy control is enabled. For example, for higher bombardment energy, such as for front-end etch applications, the 2 MHz source is used, while for softer bombardment, such as for back-end etch application, the 13 MHz bias is utilized. FIG. 2 also shows a source RF power supplier 235, operating at frequency f3, for example, 27 MHz, 60 MHz, 100 MHz, etc. The source power 235 is delivered to chamber 200 via match network 250 and is applied to the lower electrode 210. The source power is used to control the plasma density, i.e., plasma ion dissociation.

The arrangement of FIG. 2 enables superimposed application of either f1/f3 or f2/f3 frequencies to the chamber. For example, f1 can be 400 KHz to 5 MHz; f2 can be 10 MHz to 20 MHz, but normally less than 15 MHz; and f3 can be 27 MHz to 100 MHz or over. In one particular example, f1 is 2 MHz, f2 is 13.56 MHz, and f3 is 60 MHz. Such an arrangement makes it very easy to run recipes that require switching between low and high frequency bias power in mid processing.

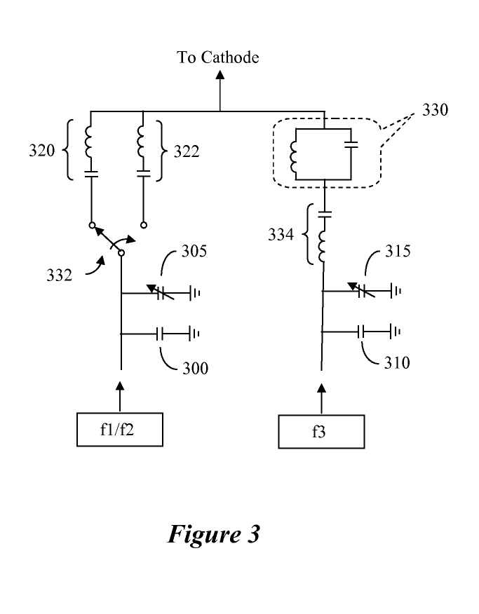

FIG. 3 illustrated an embodiment of the match circuitry wherein two out of three available frequencies are switchably applied to the cathode of a plasma chamber. A high frequency, f3 is coupled to the cathode via a match circuit 334 and a parallel resonance circuit 330, while two lower frequencies, f1 and f2, are coupled to switch 332 that switchably couples only one of them to the cathode via either of match circuits 320 or 322. In this embodiment, the two RF frequencies f1/f2 are provided by a single RF power generator that can switchably operate at either frequency f1 or frequency f2. Each of the match circuits is made of a series connection of a capacitor and an inductor. In one example, match circuit 320 has a capacitor having values of 200-500 pF and an inductor at about 20-50 mH; match circuit 322 has a capacitor having values of 50-200 pF and an inductor at about 0.5-5 mH; match circuit 320 has a capacitor having values of about 25 pF and an inductor at about 0.2-0.3 mH.

The parallel resonance circuit 330 is provided in order to prevent energy from the 13.56 MHz power source to flow into the 60 MHz source. That is, when the switch 332 couples the 2 MHz bias source, the bias frequency is thirty times smaller than the plasma source frequency of 60 MHz, so it cannot jump the match network 334. However, when the switch 332 couples the 13.56 MHz bias power, the bias frequency is much closer to the plasma source frequency f3 and it may jump the match network 334. Therefore, a parallel resonance circuit is provided and is made of a parallel connection of a capacitor and inductor. In this example, where f1=2 MHZ, f2=13.56 MHz, and f3=60 MHZ, the parallel resonance circuit 330 is centered at 13 MHz, with variance or band of Δf=2 MHZ. This prevents bias frequency 13.56 from leaking into source power supplier F3. The resonance circuit acts as a short circuit to the 60 MHz frequency.

In the example of FIG. 3, a variable shunt capacitor 305 is coupled before the switch 332, such that it is common to both match networks 320 and 322, depending on which is engaged by switch 332. Another variable shunt capacitor 315 serves the match network 334 for f3. In this embodiment, both shunt capacitors are implemented using variable vacuum capacitors. Also, in this embodiment special protection measures are implemented to protect the variable shunt capacitors. A fixed capacitor 300 is coupled in parallel to shunt capacitor 305. Fixed capacitor 300 protects shunt capacitor 305 from high RF currents when variable capacitor 305 is set for low capacitance values. Conversely, fixed capacitor 310 is coupled in parallel with variable capacitor 315. Fixed capacitor 310 protects shunt capacitor 315 from high RF currents when variable capacitor 315 is set for low capacitance values. In this example variable shunt capacitor 305 can be varied from about 30 pF to 1500 pF and capacitor 300 is selected as about 100 pF. Similarly, in this example variable shunt capacitor 315 can be varied from about 10 pF to 150 pF and capacitor 310 is selected as about 120 pF.

Any of the above embodiments can be used to operate a plasma chamber to provide a processing having a first period operating at a first bias frequency and a second period operating at a second bias frequency. For example, the chamber may be operated using a low bias frequency, e.g., about 2 MHz for the main etch step; however, in order to create a “soft landing” during the over etch the system may be switched to operate using a higher frequency bias, such as, e.g., about 13 MHz.

Finally, it should be understood that processes and techniques described herein are not inherently related to any particular apparatus and may be implemented by any suitable combination of components. Further, various types of general purpose devices may be used in accordance with the teachings described herein. It may also prove advantageous to construct specialized apparatus to perform the method steps described herein. The present invention has been described in relation to particular examples, which are intended in all respects to be illustrative rather than restrictive. Those skilled in the art will appreciate that many different combinations of hardware, software, and firmware will be suitable for practicing the present invention. For example, the described software may be implemented in a wide variety of programming or scripting languages, such as Assembler, C/C++, perl, shell, PHP, Java, etc.

The present invention has been described in relation to particular examples, which are intended in all respects to be illustrative rather than restrictive. Those skilled in the art will appreciate that many different combinations of hardware, software, and firmware will be suitable for practicing the present invention. Moreover, other implementations of the invention will be apparent to those skilled in the art from consideration of the specification and practice of the invention disclosed herein. Various aspects and/or components of the described embodiments may be used singly or in any combination in the plasma chamber arts. It is intended that the specification and examples be considered as exemplary only, with a true scope and spirit of the invention being indicated by the following claims.

1. An RF matching circuitry switchably coupling one of two bias frequencies and one source frequency to a cathode, comprising:
a switch having one input and a first and a second outputs;
a first match network having input coupled to the switch first output and output coupled to the cathode, the first match network tuned to operate at a first bias frequency below 10 MHz;
a second match network having input coupled to the switch second output and output coupled to the cathode, the second match network tuned to operate at a second bias frequency higher than the first bias frequency but below 15 MHz;
a third match network having output coupled to the cathode, the third match network tuned to operate at a source frequency higher than the second bias frequency; and,
a parallel resonance circuit coupled between the output of the third match network and the cathode, the parallel resonance circuit tuned to be centered at the same frequency as the second bias frequency.

2. The RF matching circuitry of claim 1, further comprising a variable shunt capacitor coupled between ground and the input of the switch.

3. The RF matching circuitry of claim 2, further comprising a second variable shunt capacitor coupled between ground and the input of the third match network.

4. The RF matching circuitry of claim 3, further comprising a fixed capacitor coupled between ground and the input of the switch.

5. The RF matching circuitry of claim 4, further comprising a second fixed capacitor coupled between ground and the input of the third match network.

6. An RF matching circuitry switchably coupling one of two bias frequencies to a cathode, comprising:
a switch having one input and a first and a second outputs;
a first match network having input coupled to the switch first output and output coupled to the cathode, the first match network tuned to operate at a first bias frequency below 10 MHz;
a second match network having input coupled to the switch second output and output coupled to the cathode, the second match network tuned to operate at a second bias frequency higher than the first bias frequency but below 15 MHz;
a variable shunt capacitor coupled between ground and the input of the switch; and
a fixed capacitor coupled between ground and the input of the switch.

7. A plasma processing chamber operable with two switchable RF bias power, comprising:
a chamber body configured to maintain plasma within an evacuated interior;
a cathode configured for coupling RF energy to the plasma;
a first RF power generator operable to selectively generate either a first bias frequency below 10 MHz or a second bias frequency higher than the first bias frequency but below 15 MHz;
a switch having an input coupled to the first RF power generator and having a first and second outputs;
a first match network having input coupled to the switch first output and output coupled to the cathode, the first match network tuned to operate at the first bias frequency;
a second match network having input coupled to the switch second output and output coupled to the cathode, the second match network tuned to operate at the second bias frequency;
a second RF power generator operable to generate RF source power at frequency higher than 15 MHz; and,
a third match network having input coupled to the second RF power generator and output coupled to the cathode.

8. The plasma processing chamber of claim 7, wherein the first bias frequency is about 2 MHZ, the second bias frequency is about 13 MHz, and the source power frequency is one of 27 MHz, 60 MHz, and 100 MHz.

9. The plasma processing chamber of claim 8, further comprising a parallel resonance circuit coupled between the output of the third match network and the cathode, the parallel resonance circuit tuned to be centered at about 13 MHz with a 2 MHz band.

10. The plasma processing chamber of claim 9, further comprising parallel connection of a variable shunt capacitor and a fixed capacitor coupled between ground and the input of the switch.

11. The plasma processing chamber of claim 10, further comprising parallel connection of a variable shunt capacitor and a fixed capacitor coupled between ground and the input of the third match network.
